(19) United States
(12) Patent Application Publication
(10) Pub. No.: US 2019/0364662 A1
(43) Pub. Date: Nov. 28, 2019

(54) PRINTED WIRING BOARD AND METHOD FOR MANUFACTURING PRINTED WIRING BOARD

(71) Applicant: IBIDEN CO., LTD., Ogaki (JP)

(72) Inventors: Kazuro NISHIWAKI, Ogaki (JP); Hiroaki Kodama, Ogaki (JP); Yuji Kadowaki, Ogaki (JP)

(73) Assignee: IBIDEN CO., LTD., Ogaki (JP)

(21) Appl. No.: 16/419,203

(22) Filed: May 22, 2019

(30) Foreign Application Priority Data
May 22, 2018 (JP) 2018-097836

(51) Int. Cl. H05K 1/16; H05K 1/11; H05K 3/42; H01F 27/28; H01F 41/04

(52) U.S. Cl. CPC H05K 1/165; H05K 1/115; H05K 3/423; H05K 3/429; H01F 2027/2809; H01F 41/041; H05K 2203/072; H05K 2203/0723; H01F 27/2804

(57) ABSTRACT

A printed wiring board includes a first conductor layer, a first insulating layer on the first conductor layer, a second conductor layer on the first insulating layer, a second insulating layer on the second conductor layer, a third conductor layer on the second insulating layer, a first via conductor in the first insulating layer such that the first via conductor is penetrating through the first insulating layer and connecting the first and second conductor layers, a second via conductor in the second insulating layer such that the second via conductor is penetrating through the second insulating layer and connecting the second and third conductor layers, and a magnetic resin portion formed in opening of the first insulating layer and covering part of the first conductor layer such that the second conductor layer is not formed in a region of the first insulating layer where the magnetic resin portion is formed.

### CROSS-REFERENCE TO RELATED APPLICATIONS

The present application is based upon and claims the benefit of priority to Japanese Patent Application No. 2018-097836, filed May 22, 2018, the entire contents of which are incorporated herein by reference.

### BACKGROUND OF THE INVENTION

### Field of the Invention

The present invention relates to a printed wiring board having a wiring covered by a magnetic resin, and relates to a method for manufacturing the printed wiring board.

### Description of Background Art

Japanese Patent Laid-Open Publication No. 2014-32978 describes an inductor component in which a magnetic layer and a resin layer are provided on each of multiple layers of inductor patterns. The entire contents of this publication are incorporated herein by reference.

### SUMMARY OF THE INVENTION

According to one aspect of the present invention, a printed wiring board includes a first conductor layer, a first resin insulating layer formed on the first conductor layer, a second conductor layer formed on the first resin insulating layer, a second resin insulating layer formed on the second conductor layer, a third conductor layer formed-on the second resin insulating layer, a first via conductor formed in the first resin insulating layer such that the first via conductor is penetrating through the first resin insulating layer and connecting the first conductor layer and the second conductor layer, a second via conductor formed in the second resin insulating layer such that the second via conductor is penetrating through the second resin insulating layer and connecting the second conductor layer and the third conductor layer, and a magnetic resin portion formed in an opening of the first resin insulating layer such that the magnetic resin portion is covering part of the first conductor layer and that the second conductor layer is not formed in a region of the first resin insulating layer where the magnetic resin portion is formed.

According to another aspect of the present invention, a method for manufacturing a printed wiring board includes forming a first conductor layer on a support plate, forming a first resin insulating layer on the first conductor layer, forming a first via conductor in the first resin insulating layer and a via land of the first via conductor on the first resin insulating layer, forming a through hole in the first resin insulating layer such that the through hole exposes part of the first conductor layer, and filling a magnetic resin into the through hole formed in the first resin insulating layer such that the magnetic resin portion covering the part of the first conductor layer is formed in the first resin insulating layer.

According to yet another aspect of the present invention, a method for manufacturing a printed wiring board includes forming a first conductor layer on a support plate, forming a magnetic resin portion on the first conductor layer, forming a first resin insulating layer on the support plate such that the first resin insulating layer covers the magnetic resin portion, forming a first via conductor in the first resin insulating layer and a via land of the first via conductor on the first resin insulating layer, forming a second resin insulating layer on the first resin insulating layer such that the second resin insulating layer covers the via land of the first via conductor, and forming a second via conductor in the second resin insulating layer and a via land of the second via conductor on the second resin insulating layer such that the second via conductor connects to the via land of the first via conductor.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view of a printed wiring board according to a first embodiment of the present invention;

FIG. 1B is a b-b cross-sectional view of the printed wiring board of FIG. 1A;

FIGS. 2A-2D are manufacturing process diagrams of the printed wiring board of the first embodiment;

FIGS. 3A-3D are manufacturing process diagrams of the printed wiring board of the first embodiment;

FIGS. 4A and 4B are manufacturing process diagrams of the printed wiring board of the first embodiment;

FIGS. 5A-5D are manufacturing process diagrams of a printed wiring board of a first modified embodiment of the first embodiment;

FIG. 6 is a cross-sectional view of a printed wiring board according to a second modified embodiment of the first embodiment;

FIGS. 7A-7D are manufacturing process diagrams of the printed wiring board of the second modified embodiment of the first embodiment;

FIGS. 8A-8D are manufacturing process diagrams of the printed wiring board of the second modified embodiment of the first embodiment;

FIG. 9 is a cross-sectional view of a printed wiring board of a second embodiment;

FIGS. 10A-10D are manufacturing process diagrams of the printed wiring board of the second embodiment; and

FIGS. 11A-11D are manufacturing process diagrams of the printed wiring board of the second embodiment.

### DETAILED DESCRIPTION OF THE EMBODIMENTS

Embodiments will now be described with reference to the accompanying drawings, wherein like reference numerals designate corresponding or identical elements throughout the various drawings.

### First Embodiment

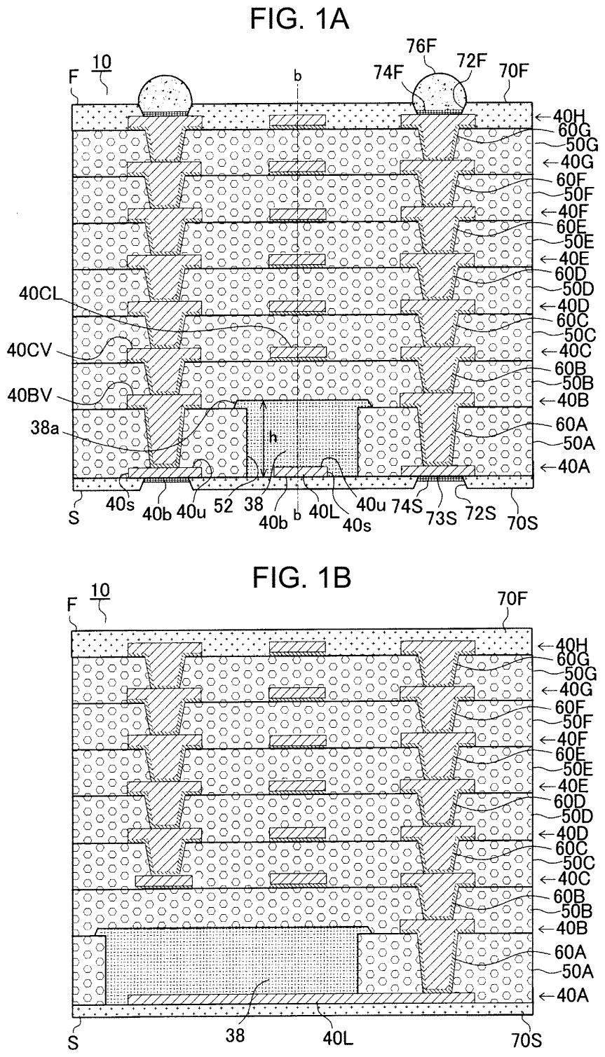

FIG. 1A is a cross-sectional view of a printed wiring board according to a first embodiment of the present invention. FIG. 1B is a b-b cross-sectional view of the printed wiring board of FIG. 1A.

The printed wiring board 10 has a first surface (F) and a second surface (S) on an opposite side with respect to the first surface (F), and has a lowermost first resin insulating layer (50A), a first conductor layer (40A) formed on the second surface (S) side of the first resin insulating layer, a second conductor layer (40B) formed on the first surface (F) side of the first resin insulating layer, and first via conductors (60A) that penetrate the first resin insulating layer (50A) and connect the first conductor layer (40A) and the second conductor layer (40B) to each other. A through hole 52 is provided in the first resin insulating layer (50A), and a magnetic resin 38 is filled in the through hole 52. A part of the magnetic resin 38 overflows from the through hole 52 to form a flange part (38a). An inductor pattern (40L) included in the first conductor layer (40A) is covered by the magnetic resin 38 filled in the through hole 52. That is, a side surface (40s) and an upper surface (40u) of the inductor pattern (40L) are embedded in the magnetic resin 38, and a lower surface (40b) of the inductor pattern (40L) is exposed from the magnetic resin 38. Similarly, side surfaces (40s) and upper surfaces (40u) of other parts of the first conductor layer (40A) are embedded in the first resin insulating layer (50A), and lower surfaces (40b) of the other parts of the first conductor layer (40A) are exposed from the first resin insulating layer (50A). The second conductor layer (40B) includes via lands (40BV) of the first via conductors (60A). The second conductor layer is not formed in a region directly above the magnetic resin 38.

A second resin insulating layer (50B) is provided on the first resin insulating layer (50A) and the second conductor layer (40B), and a third conductor layer (40C) is provided on the second resin insulating layer (50B). The second conductor layer (40B) and the third conductor layer (40C) are connected to each other by second via conductors (60B) that penetrate the second resin insulating layer (50B). The third conductor layer (40C) includes via lands (40CV) of the second via conductors (60B), and a conductor circuit (40CL). The conductor circuit (40CL) is also formed in a region directly above the magnetic resin 38.

A third resin insulating layer (50C) is provided on the second resin insulating layer (50B) and the third conductor layer (40C), and a fourth conductor layer (40D) is provided on the third resin insulating layer (50C). The third conductor layer (40C) and the fourth conductor layer (40D) are connected to each other by third via conductors (60C) that penetrate the third resin insulating layer (50C).

A fourth resin insulating layer (50D) is provided on the third resin insulating layer (50C) and the fourth conductor layer (40D), and a fifth conductor layer (40E) is provided on the fourth resin insulating layer (50D). The fourth conductor layer (40D) and the fifth conductor layer (40E) are connected to each other by fourth via conductors (60D) that penetrate the fourth resin insulating layer (50D).

A fifth resin insulating layer (50E) is provided on the fourth resin insulating layer (50D) and the fifth conductor layer (40E), and a sixth conductor layer (40F) is provided on the fifth resin insulating layer (50E). The fifth conductor layer (40E) and the sixth conductor layer (40F) are connected to each other by fifth via conductors (60E) that penetrate the fifth resin insulating layer (50E).

A sixth resin insulating layer (50F) is provided on the fifth resin insulating layer (50E) and the sixth conductor layer (40F), and a seventh conductor layer (40G) is provided on the sixth resin insulating layer (50F). The sixth conductor layer (40F) and the seventh conductor layer (40G) are connected to each other by sixth via conductors (60F) that penetrate the sixth resin insulating layer (50F).

A seventh resin insulating layer (50G) is provided on the sixth resin insulating layer (50F) and the seventh conductor layer (40G), and an eighth conductor layer (40H) is provided on the seventh resin insulating layer (50G). The seventh conductor layer (40G) and the eighth conductor layer (40H) are connected to each other by seventh via conductors (60G) that penetrate the seventh resin insulating layer (50G).

A first solder resist layer (70F) having openings (72F) is formed on the seventh resin insulating layer (50G) and the eighth conductor layer (40H). A corrosion resistant layer (74F) formed of, for example, a Ni/Pd/Au film is formed in the openings (72F) of the first solder resist layer (70F). Solder bumps (76F) are formed on the corrosion resistant layer (74F).

A second solder resist layer (70S) having openings (72S) is formed on the second surface (S) of the first resin insulating layer (50A) and the lower surface (40b) of the first conductor layer (40A). The lower surface (40b) of the first conductor layer (40A) exposed from the openings (72S) forms pads (73S) for connecting to an external substrate. A corrosion resistant layer (74S) formed of, for example, a Ni/Pd/Au film is formed on the pads (73S). As illustrated in FIG. 1B, a part of the inductor pattern (40L) exposed from the magnetic resin 38 is connected to one of the first via conductors (60A).

According to the printed wiring board 10 of the first embodiment, the second conductor layer (40B) is not formed in a region directly above the magnetic resin 38. Therefore, an insulation distance between the magnetic resin 38 and the second conductor layer (40B) is not a problem. Therefore, a thickness (h) of the magnetic resin 38 can be increased, and a high inductance can be obtained. Further, the first conductor layer (40A) and the third conductor layer (40C) as a conductor layer above the first conductor layer are connected to each other by the first via conductors (60A) and the second via conductors (60B). Therefore, as compared to forming a single via conductor that penetrates the first resin insulating layer (50A) and the second resin insulating layer (50B), heights of the first via conductors (60A) and the second via conductors (60B) can be reduced and connection reliability can be improved.

### Manufacturing Method of First Embodiment

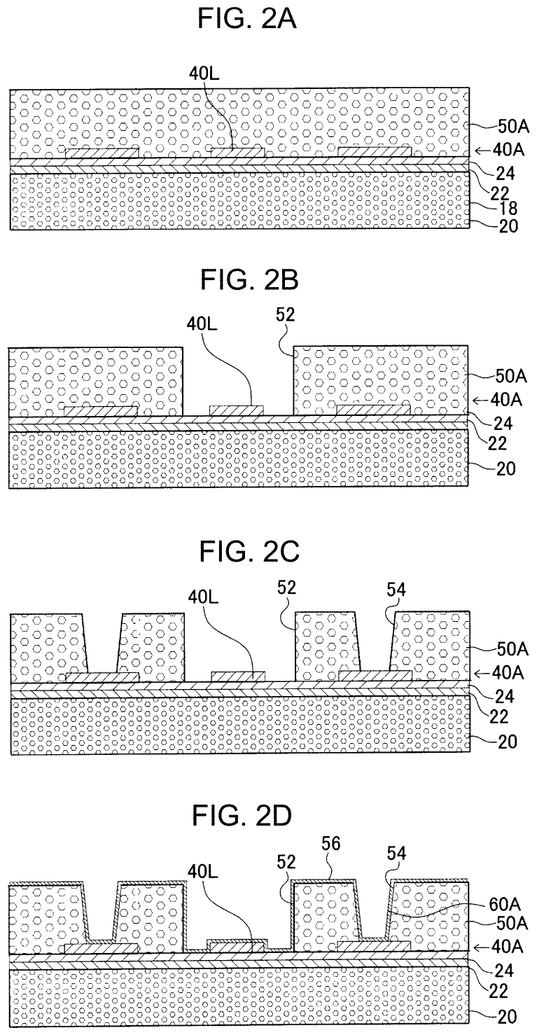

A method for manufacturing the printed wiring board of the first embodiment is illustrated in FIGS. 2A-4B.

A copper-clad laminated plate (support plate) 20 formed by laminating a copper foil 22 on a resin substrate 18, and a copper foil 24 are prepared. The copper foil 24 is bonded to the copper-clad laminated plate 20, and the first conductor layer (40A) formed of copper plating is formed on the copper foil 24. The first conductor layer (40A) includes the inductor pattern (40L). The first resin insulating layer (50A) is formed on the copper foil 24 and the first conductor layer (40A) (FIG. 2A).

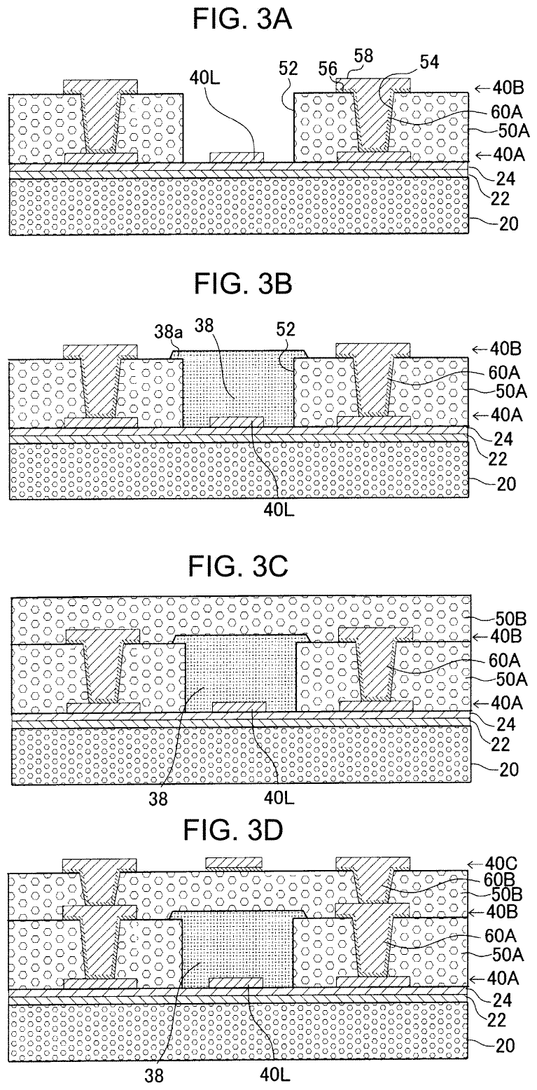

The through hole 52 exposing the inductor pattern (40L) is formed in the first resin insulating layer (50A) using laser so as to penetrate the first resin insulating layer (50A) (FIG. 2B). Via openings 54 reaching the first conductor layer (40A) for forming via conductors are formed in the first resin insulating layer (50A) using laser (FIG. 2C). An electroless plating film 56 is formed in the through hole 52, in the via openings 54, and on a surface of the first resin insulating layer (50A) (FIG. 2D). Further, the first via conductors (60A) are formed in the via openings 54 by electrolytic plating, and the second conductor layer (40B) is formed on the electroless plating film 56 exposed from a plating resist (not illustrated in the drawings). After the plating resist is peeled off, the electroless plating film 56 exposed from the electrolytic plating film 58 is removed (FIG. 3A). The magnetic resin 38 is filled in the through hole 52 of the first resin insulating layer (50A) exposing the inductor pattern (40L) (FIG. 3B). A part (38a) of the magnetic resin 38 overflows to the surface of the first resin insulating layer (50A). As a result, the thickness of the magnetic resin 38 can be larger than that of the first resin insulating layer (50A).

The second resin insulating layer (50B) is formed on the first resin insulating layer (50A) and on the second conductor layer (40B) and the magnetic resin 38 (FIG. 3C). The third conductor layer (40C) is formed on the second resin insulating layer (50B), and the second via conductors (60B) penetrating the second resin insulating layer (50B) are formed (FIG. 3D).

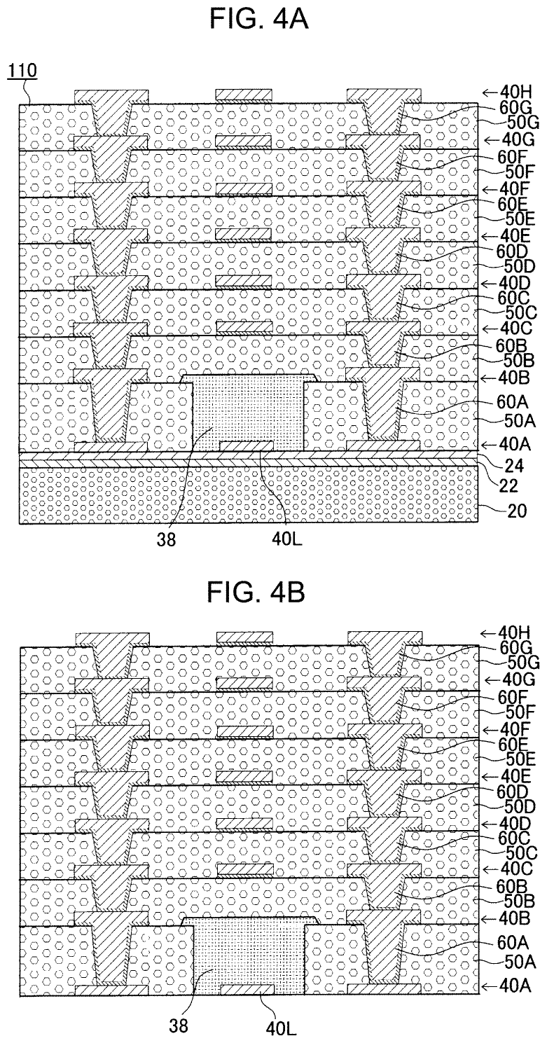

The processes of FIGS. 3C and 3D are repeated, and the third resin insulating layer (50C), the third via conductors (60C), and the fourth conductor layer (40D) are formed, the fourth resin insulating layer (50D), the fourth via conductors (60D), and the fifth conductor layer (40E) are formed, the fifth resin insulating layer (50E), the fifth via conductors (60E), and the sixth conductor layer (40F) are formed, the sixth resin insulating layer (50F), the sixth via conductors (60F), and the seventh conductor layer (40G) are formed, and the seventh resin insulating layer (50G), the seventh via conductors (60G), and the eighth conductor layer (40H) are formed, and an intermediate 110 is completed (FIG. 4A).

The copper-clad laminated plate 20 in which the copper foil 22 is laminated is separated from the intermediate 110, and the copper foil 24 is removed by etching (FIG. 4B). The first solder resist layer (70F) having the openings (72F) is formed on the seventh resin insulating layer (50G) and the eighth conductor layer (40H), the second solder resist layer (70S) having the openings (72S) is formed on the second surface (S) of the first resin insulating layer (50A) and the lower surface (40b) of the first conductor layer (40A), the corrosion resistant layer (74F) is formed in the openings (72F) of the first solder resist layer (70F), the solder bumps (76F) are formed on the corrosion resistant layer (74F), the corrosion resistant layer (74S) is formed on the pads (73S) exposed from the openings (72S), and the printed wiring board 10 is completed (FIG. 1A).

According to the method for manufacturing the printed wiring board of the first embodiment, the through hole 52 exposing a part of the first conductor layer (40A) covered by a magnetic resin is formed in the first resin insulating layer (50A), and the magnetic resin 38 is filled in the through hole 52. That is, the magnetic resin 38 of the thickness of the first resin insulating layer (50A) can be coated on the first conductor layer (40A). Further, the first conductor layer (40A) and the third conductor layer (40C) as a conductor layer above the first conductor layer are connected to each other by the first via conductors (60A) and the second via conductors (60B). Therefore, heights of the first via conductors (60A) and the second via conductors (60B) can be reduced, and connection reliability can be improved while a plating time is shortened. The magnetic resin 38 is mounted in advance on the highly rigid copper-clad laminated plate 20 by printing or the like, and the second resin insulating layer (50B) is coated on the magnetic resin 38. Therefore, adhesion between the magnetic resin 38 and the second resin insulating layer (50B) can be improved. Further, in the first resin insulating layer, the through hole 52 is formed using laser. Therefore, positional accuracy of the magnetic resin 38 can be improved.

### Manufacturing Method of First Modified Embodiment of First Embodiment

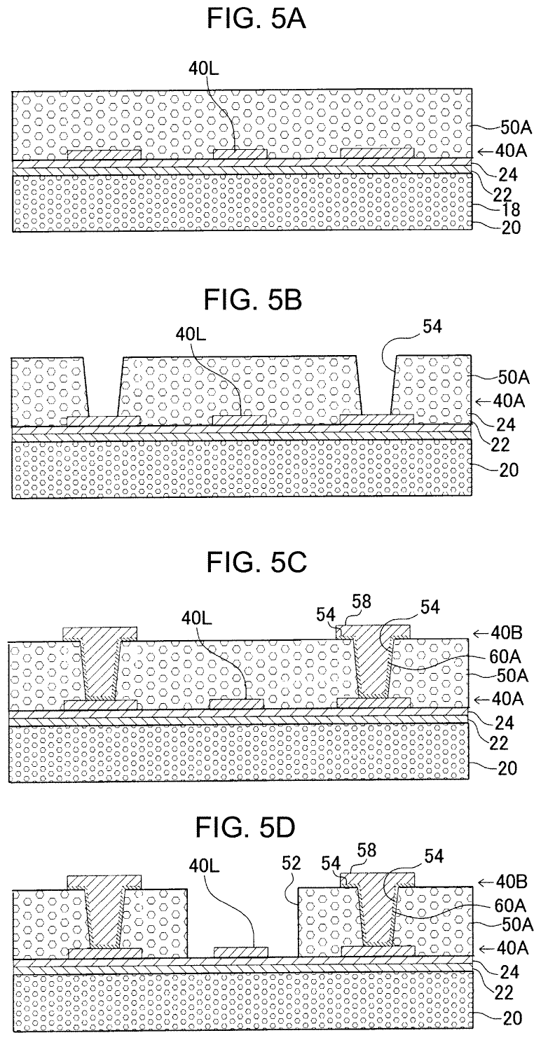

A method for manufacturing a printed wiring board according to a first modified embodiment of the first embodiment is illustrated in FIGS. 5A-5D.

A copper-clad laminated plate (support plate) 20 formed by laminating a copper foil 22 on a resin substrate 18, and a copper foil 24 are prepared. The copper foil 24 is bonded to the copper-clad laminated plate 20, and the first conductor layer (40A) formed of copper plating is formed on the copper foil 24. The first conductor layer (40A) includes the inductor pattern (40L). The first resin insulating layer (50A) is formed on the copper foil 24 and the first conductor layer (40A) (FIG. 5A).

The via openings 54 reaching the first conductor layer (40A) for forming via conductors are formed in the first resin insulating layer (50A) using laser (FIG. 5B). An electroless plating film 56 (not illustrated in the drawings) is formed in the via openings 54 and on the surface of the first resin insulating layer (50A). Further, the first via conductors (60A) are formed in the via openings 54 by electrolytic plating, and the second conductor layer (40B) is formed on the electroless plating film 56 exposed from a plating resist (not illustrated in the drawings). After the plating resist is peeled off, the electroless plating film 56 exposed from the electrolytic plating film 58 is removed (FIG. 5C).

The through hole 52 exposing the inductor pattern (40L) is formed in the first resin insulating layer (50A) using laser so as to penetrate the first resin insulating layer (50A) (FIG. 5D). Subsequent processes are the same as those of the manufacturing method of the first embodiment after FIG. 3B.

### Printed Wiring Board of Second Modified Embodiment of First Embodiment

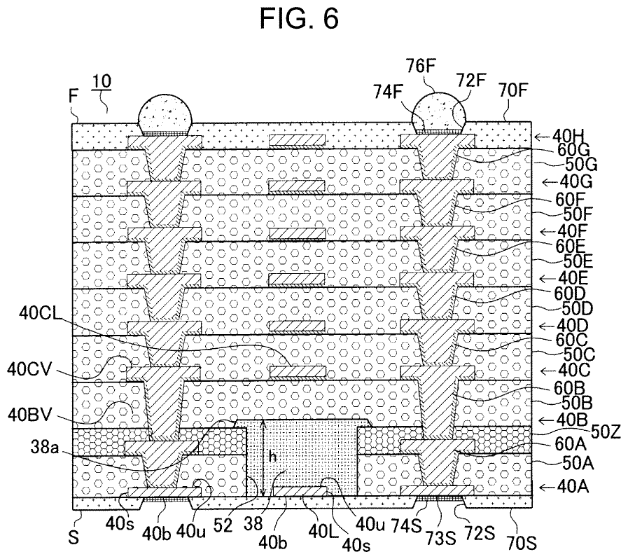

FIG. 6 illustrates a cross section of a printed wiring board according to a second modified embodiment of the first embodiment.

In the printed wiring board of the second modified embodiment of the first embodiment, an eighth resin insulating layer (third resin insulating layer) (50Z) is formed on the first resin insulating layer (50A), and the magnetic resin 38 is filled in a through hole 52 penetrating the first resin insulating layer (50A) and the eighth resin insulating layer (50Z). Then, second via conductors (60B) penetrating the eighth resin insulating layer (50Z) and the second resin insulating layer (50B) are formed.

### Manufacturing Method of Second Modified Embodiment of First Embodiment

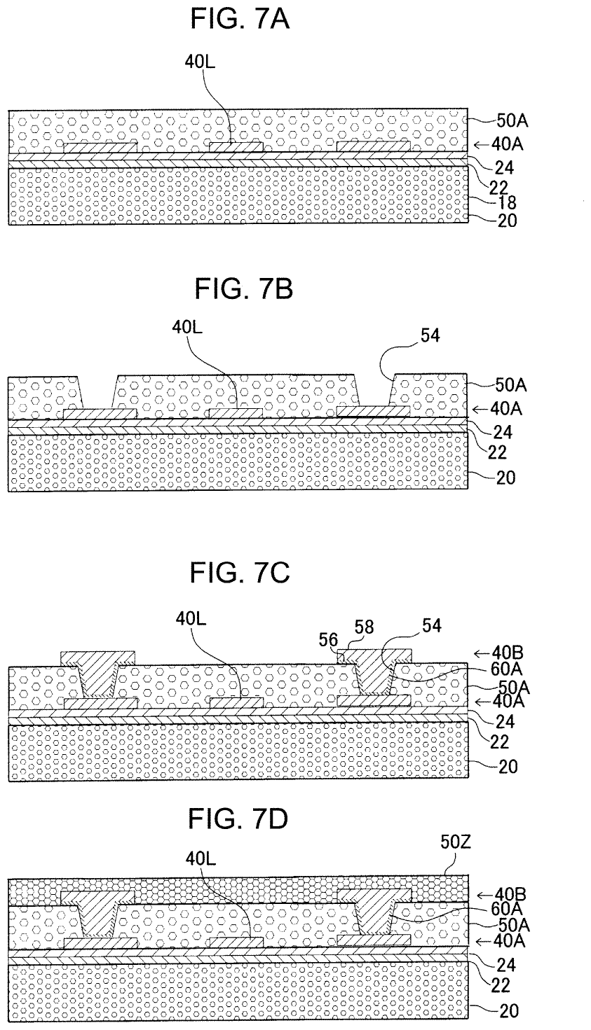

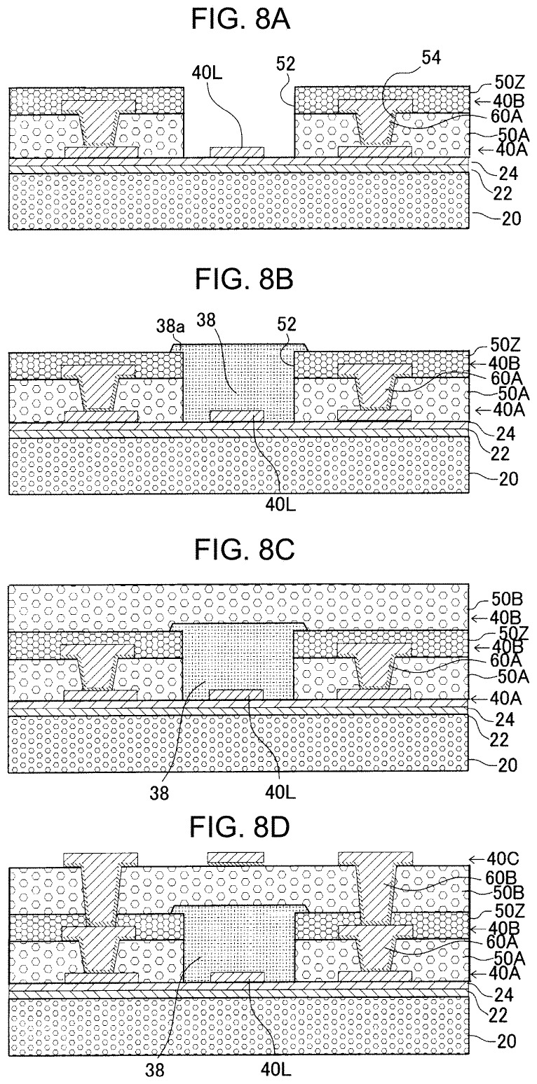

A method for manufacturing a printed wiring board according to the second modified embodiment of the first embodiment is illustrated in FIGS. 7A-8D.

A copper-clad laminated plate (support plate) 20 formed by laminating a copper foil 22 on a resin substrate 18, and a copper foil 24 are prepared. The copper foil 24 is bonded to the copper-clad laminated plate 20, and the first conductor layer (40A) formed of copper plating is formed on the copper foil 24. The first conductor layer (40A) includes the inductor pattern (40L). The first resin insulating layer (50A) is formed on the copper foil 24 and the first conductor layer (40A) (FIG. 7A).

The via openings 54 reaching the first conductor layer (40A) for forming via conductors are formed in the first resin insulating layer (50A) using laser (FIG. 7B). An electroless plating film 56 (not illustrated in the drawings) is formed in the via openings 54 and on the surface of the first resin insulating layer (50A). Further, the first via conductors (60A) are formed in the via openings 54 by electrolytic plating, and the second conductor layer (40B) is formed on the electroless plating film 56 exposed from a plating resist (not illustrated in the drawings). After the plating resist is peeled off, the electroless plating film 56 exposed from the electrolytic plating film 58 is removed (FIG. 7C).

The eighth resin insulating layer (third resin insulating layer) (50Z) is formed on the first resin insulating layer (50A) and the second conductor layer (40B) (FIG. 7D). The through hole 52 exposing the inductor pattern (40L) is formed using laser so as to penetrate the first resin insulating layer (50A) and the eighth resin insulating layer (50Z) (FIG. 8A). The magnetic resin 38 is filled in the through hole 52 of the first resin insulating layer (50A) exposing the inductor pattern (40L) (FIG. 8B).

The second resin insulating layer (50B) is formed on the eighth resin insulating layer (50Z) and on the second conductor layer (40B) and the magnetic resin 38 (FIG. 8C). The third conductor layer (40C) is formed on the second resin insulating layer (50B), and the second via conductors (60B) penetrating the second resin insulating layer (50B) are formed (FIG. 8D).

Subsequent processes are the same as those of the manufacturing method of the first embodiment after FIG. 4A.

### Second Embodiment

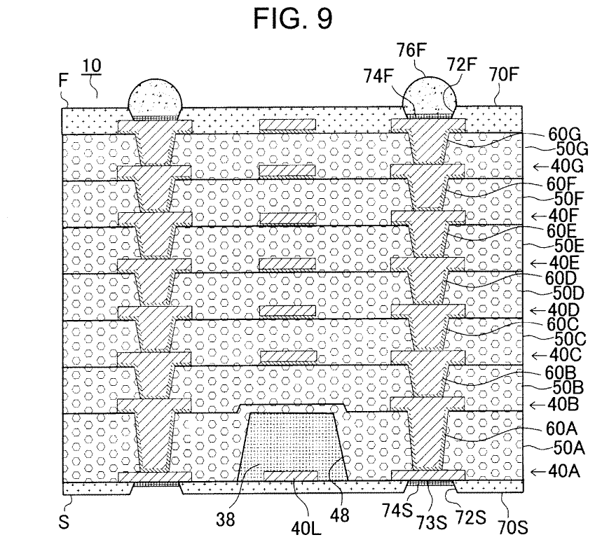

FIG. 9 illustrates a printed wiring board of a second embodiment.

In the second embodiment, the magnetic resin 38 is filled in a recess 48 that has a trapezoidal cross-sectional shape and does not penetrate the first resin insulating layer (50A). The second resin insulating layer (50B) is formed on the magnetic resin 38 via the first resin insulating layer (50A).

### Manufacturing Method of Second Embodiment

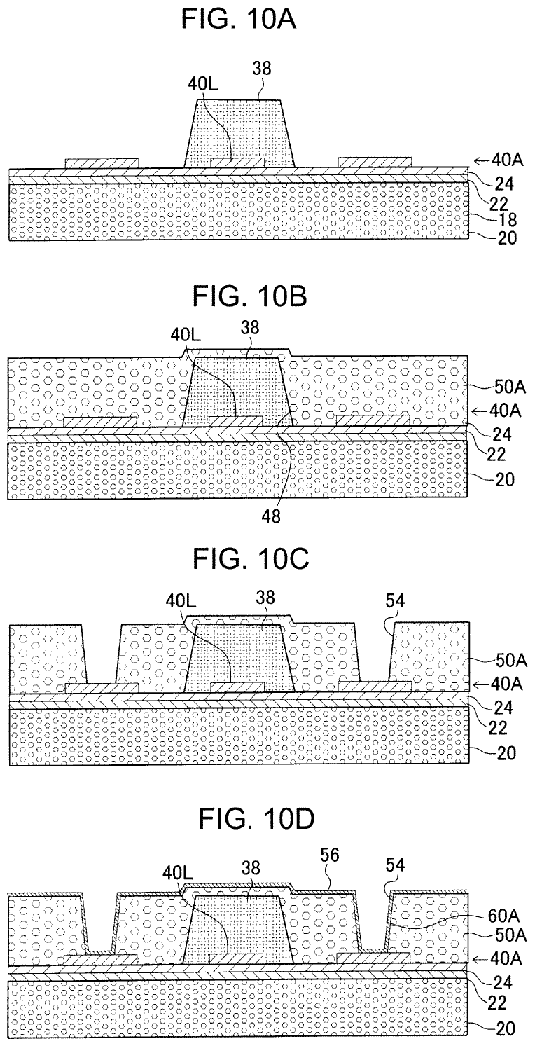

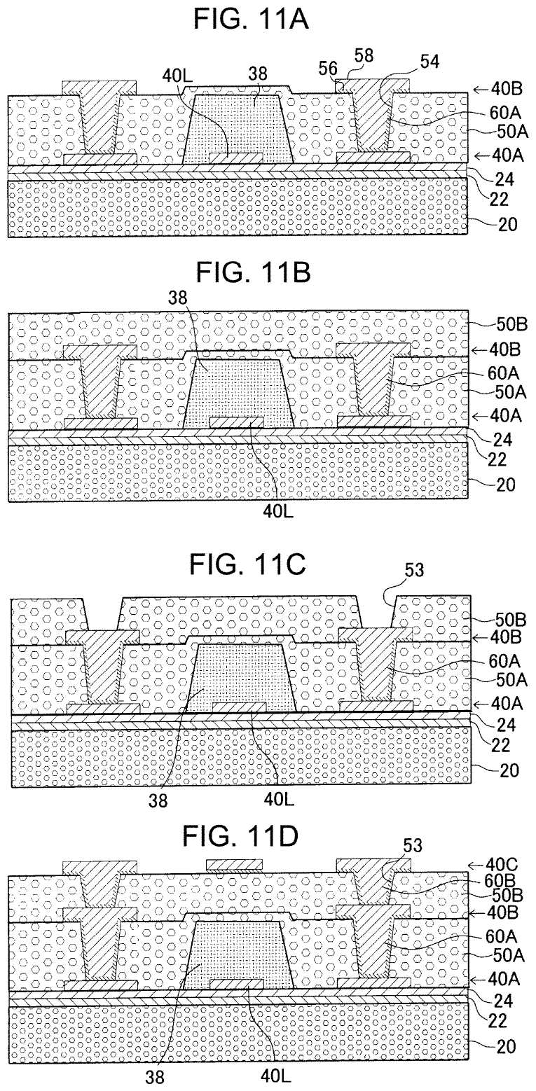

A method for manufacturing the printed wiring board of the second embodiment is illustrated in FIGS. 10A-11D.

A copper-clad laminated plate (support plate) 20 formed by laminating a copper foil 22 on a resin substrate 18, and a copper foil 24 are prepared. The copper foil 24 is bonded to the copper-clad laminated plate 20, and the first conductor layer (40A) formed of copper plating is formed on the copper foil 24. The first conductor layer (40A) includes the inductor pattern (40L). The magnetic resin 38 is formed on the inductor pattern (40L) (FIG. 10A). The first resin insulating layer (50A) is formed on the magnetic resin 38, the copper foil 24 and the first conductor layer (40A) (FIG. 10B). In this case, the recess 48 is formed in the first resin insulating layer (50A).

Via openings 54 reaching the first conductor layer (40A) for forming via conductors are formed in the first resin insulating layer (50A) using laser (FIG. 10C). An electroless plating film 56 is formed in the via openings 54, and on the surface of the first resin insulating layer (50A) (FIG. 10D). Further, the first via conductors (60A) are formed in the via openings 54 by electrolytic plating, and the second conductor layer (40B) is formed on the electroless plating film 56 exposed from a plating resist (not illustrated in the drawings). After the plating resist is peeled off, the electroless plating film 56 exposed from the electrolytic plating film 58 is removed (FIG. 11A).

The second resin insulating layer (50B) is formed on the first resin insulating layer (50A) and on the second conductor layer (40B) (FIG. 11B). Via openings 53 are formed in the second resin insulating layer (50B) (FIG. 11C). The third conductor layer (40C) is formed on the second resin insulating layer (50B), and the second via conductors (60B) penetrating the second resin insulating layer (50B) are formed in the openings 53 (FIG. 11D). Subsequent processes of the manufacturing method of the second embodiment are the same as those in the first embodiment.

According to the method for manufacturing the printed wiring board of the second embodiment, the magnetic resin 38 is mounted in advance on the highly rigid copper-clad laminated plate 20 by printing or the like, and the first resin insulating layer (50A) is coated on the magnetic resin 38. Therefore, adhesion between the magnetic resin 38 and the first resin insulating layer (50A) can be improved. Further, the first conductor layer (40A) and the third conductor layer (40C) as a conductor layer above the first conductor layer are connected to each other by the first via conductors (60A) and the second via conductors (60B). Therefore, heights of the first via conductors (60A) and the second via conductors (60B) can be reduced, and connection reliability can be improved while a plating time is shortened. Further, the thickness of the magnetic resin 38 can be set independent of the thickness of the first resin insulating layer (50A).

In Japanese Patent Laid-Open Publication No. 2014-32978, since an upper-layer inductor pattern is superimposed on an inductor pattern, a thickness of a magnetic layer provided on an inductor pattern is limited.

A printed wiring board according to an embodiment of the present invention includes: a first conductor layer as a lowermost layer; a second conductor layer above the first conductor layer; a third conductor layer above the second conductor layer; a first resin insulating layer between the first conductor layer and the second conductor layer; a second resin insulating layer between the second conductor layer and the third conductor layer; a first via conductor that penetrates the first resin insulating layer and connects the first conductor layer and the second conductor layer to each other; a second via conductor that penetrates the second resin insulating layer and connects the second conductor layer and the third conductor layer; and a magnetic resin that is provided in a lower side opening of the first resin insulating layer and covers a part of the first conductor layer. The second conductor layer is not formed in a region where the magnetic resin is provided.

A method for manufacturing a printed wiring board according to an embodiment of the present invention includes: forming a first conductor layer on a support plate; forming a first resin insulating layer on the support plate and the first conductor layer; forming, in the first resin insulating layer, a through hole that exposes a part of the first conductor layer, the part being to be covered by a magnetic resin; forming, in the first resin insulating layer, an opening for forming a via conductor; forming a first via conductor in the opening and forming a via land of the first via conductor on the first resin insulating layer; filling the through hole with a magnetic resin; forming a second resin insulating layer on the first resin insulating layer and the magnetic resin; and forming a second via conductor that penetrates the second resin insulating layer and reaches the via land, and forming a third conductor layer on the second resin insulating layer.

A method for manufacturing a printed wiring board according to another embodiment of the preset invention includes: forming a first conductor layer on a support plate; forming a magnetic resin on the first conductor layer; forming a first resin insulating layer on the magnetic resin and the support plate; forming, in the first resin insulating layer, an opening for forming a via conductor; forming a first via conductor in the opening and forming a via land of the first via conductor on the first resin insulating layer; forming a second resin insulating layer on the first resin insulating layer; and forming a second via conductor that penetrates the second resin insulating layer and reaches the via land, and forming a third conductor layer on the second resin insulating layer.

In a printed wiring board according to an embodiment of the present invention, the second conductor layer is not formed in a region where the magnetic resin is provided. Therefore, an insulation distance between the magnetic resin and the second conductor layer is not a problem. Therefore, a thickness of the magnetic resin can be increased, and a high inductance can be obtained. Further, the first conductor layer and the third conductor layer as a conductor layer above the first conductor layer are connected to each other by the first via conductor and the second via conductor. Therefore, heights of the first via conductor and the second via conductor can be reduced, and connection reliability can be improved.

In a method for manufacturing a printed wiring board according to an embodiment of the present invention, the through hole exposing a part of the first conductor layer covered by the magnetic resin is formed in the first resin insulating layer, and the magnetic resin is filled in the through hole. That is, the magnetic resin of a thickness of the first resin insulating layer can be coated on the first conductor layer. Therefore, a high inductance can be obtained. Further, the first conductor layer and the third conductor layer as a conductor layer above the first conductor layer are connected to each other by the first via conductor and the second via conductor. Therefore, the heights of the first via conductor and the second via conductor can be reduced, and, connection reliability can be improved while a plating time is shortened. The magnetic resin is mounted in advance on the highly rigid support plate by printing or the like, and the second resin insulating layer is coated on the magnetic resin. Therefore, adhesion between the magnetic resin and the second resin insulating layer can be improved.

In a method for manufacturing a printed wiring board according to another embodiment of the present invention, the first resin insulating layer is provided on the magnetic resin, and the second resin insulating layer is further provided. Different from providing the second resin insulating layer on the magnetic resin, the second resin insulating layer is provided on the first resin insulating layer, and adhesion is high. Therefore, reliability of the first resin insulating layer and the second resin insulating layer is high. The magnetic resin is mounted in advance on the highly rigid support plate by printing or the like, and the first resin insulating layer is coated on the magnetic resin. Therefore, adhesion between the magnetic resin and the first resin insulating layer can be improved. Further, the first conductor layer and the third conductor layer as a conductor layer above the first conductor layer are connected to each other by the first via conductor and the second via conductor. Therefore, the heights of the first via conductor and the second via conductor can be reduced, and connection reliability can be improved while a plating time is shortened.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a first conductor layer;
a first resin insulating layer formed on the first conductor layer;
a second conductor layer formed on the first resin insulating layer;
a second resin insulating layer formed on the second conductor layer;
a third conductor layer formed on the second resin insulating layer;
a first via conductor formed in the first resin insulating layer such that the first via conductor is penetrating through the first resin insulating layer and connecting the first conductor layer and the second conductor layer;
a second via conductor formed in the second resin insulating layer such that the second via conductor is penetrating through the second resin insulating layer and connecting the second conductor layer and the third conductor layer; and
a magnetic resin portion formed in an opening of the first resin insulating layer such that the magnetic resin portion is covering part of the first conductor layer and that the second conductor layer is not formed in a region of the first resin insulating layer where the magnetic resin portion is formed.

2. The printed wiring board according to claim 1, wherein the second conductor layer includes a via land of the first via conductor.

3. The printed wiring board according to claim 1, wherein the first conductor layer is formed such that an upper surface and a side surface of the first conductor layer are embedded in the first resin insulating layer or the magnetic resin, and that a lower surface of the first conductor layer is exposed from the first resin insulating layer or the magnetic resin.

4. The printed wiring board according to claim 1, wherein the first resin insulating layer is formed such that the opening is a through hole penetrating through the first resin insulating layer.

5. The printed wiring board according to claim 4, wherein the magnetic resin has a flange portion protruding from the through hole.

6. The printed wiring board according to claim 1, wherein the first resin insulating layer is formed such that the opening is a recess that does not penetrate through the first resin insulating layer.

7. The printed wiring board according to claim 1, wherein the first via conductor and the second via conductor form a stacked via structure such that the second via conductor is formed directly on the first via conductor.

8. The printed wiring board according to claim 2, wherein the first conductor layer is formed such that an upper surface and a side surface of the first conductor layer are embedded in the first resin insulating layer or the magnetic resin, and that a lower surface of the first conductor layer is exposed from the first resin insulating layer or the magnetic resin.

9. The printed wiring board according to claim 2, wherein the first resin insulating layer is formed such that the opening is a through hole penetrating through the first resin insulating layer.

10. The printed wiring board according to claim 9, wherein the magnetic resin has a flange portion protruding from the through hole.

11. The printed wiring board according to claim 2, wherein the first resin insulating layer is formed such that the opening is a recess that does not penetrate through the first resin insulating layer.

12. The printed wiring board according to claim 2, wherein the first via conductor and the second via conductor form a stacked via structure such that the second via conductor is formed directly on the first via conductor.

13. The printed wiring board according to claim 3, wherein the first resin insulating layer is formed such that the opening is a through hole penetrating through the first resin insulating layer.

14. The printed wiring board according to claim 13, wherein the magnetic resin has a flange portion protruding from the through hole.

15. The printed wiring board according to claim 3, wherein the first resin insulating layer is formed such that the opening is a recess that does not penetrate through the first resin insulating layer.

16. A method for manufacturing a printed wiring board, comprising:
forming a first conductor layer on a support plate;
forming a first resin insulating layer on the first conductor layer;
forming a first via conductor in the first resin insulating layer and a via land of the first via conductor on the first resin insulating layer;
forming a through hole in the first resin insulating layer such that the through hole exposes part of the first conductor layer; and
filling a magnetic resin into the through hole formed in the first resin insulating layer such that the magnetic resin portion covering the part of the first conductor layer is formed in the first resin insulating layer.

17. The method for manufacturing a printed wiring board according to claim 16 further comprising:
forming a second resin insulating layer on the first resin insulating layer such that the second resin insulating layer covers the magnetic resin portion and the via land of the first via conductor on the first resin insulating layer; and
forming a second via conductor in the second resin insulating layer such that the second via conductor connects to the via land the first via conductor on the first resin insulating layer.

18. The method for manufacturing a printed wiring board according to claim 16, further comprising:
forming a third resin insulating layer on the first resin insulating layer after the forming of the first via conductor and the via land of the first via conductor such that the third resin insulating layer covers the via land of the first via conductor on the first resin insulating layer,
wherein the forming of the through hole in the first resin insulating layer comprises forming the through hole in the first resin insulating layer and the third resin insulating layer such that the through hole exposes the part of the first conductor layer, the filling comprises filling the magnetic resin into the through hole formed in the first resin insulating layer and the third resin insulating layer such that the magnetic resin portion covering the part of the first conductor layer is formed in the first resin insulating layer and the third resin insulating layer.

19. The method for manufacturing a printed wiring board according to claim 18, further comprising:
forming a second resin insulating layer on the third resin insulating layer such that the second resin insulating layer covers the magnetic resin formed in the first resin insulating layer and the third resin insulating layer; and
forming a second via conductor in the second resin insulating layer and the third resin insulating layer and a via land of the second via conductor on the second resin insulating layer such that the second via conductor connects to the via land of the first via conductor.

20. A method for manufacturing a printed wiring board, comprising:
forming a first conductor layer on a support plate;
forming a magnetic resin portion on the first conductor layer;
forming a first resin insulating layer on the support plate such that the first resin insulating layer covers the magnetic resin portion;
forming a first via conductor in the first resin insulating layer and a via land of the first via conductor on the first resin insulating layer;
forming a second resin insulating layer on the first resin insulating layer such that the second resin insulating layer covers the via land of the first via conductor; and
forming a second via conductor in the second resin insulating layer and a via land of the second via conductor on the second resin insulating layer such that the second via conductor connects to the via land of the first via conductor.
